(19) United States
(12) Patent Application Publication
(10) Pub. No.: US 2026/0191054 A1
(43) Pub. Date: Jul. 2, 2026

(54) SEMICONDUCTOR PACKAGE

(71) Applicant: Samsung Electronics Co., Ltd., Suwon-si (KR)

(72) Inventors: HONGJIN KIM, Suwon-si (KR); KI-HONG JEONG, Suwon-si (KR); Eunhye LEE, Suwon-si (KR)

(21) Appl. No.: 19/315,567

(22) Filed: Aug. 31, 2025

(30) Foreign Application Priority Data
Dec. 26, 2024 (KR) 10-2024-0197661

(51) Int. Cl. H01L 23/498; H01L 21/48; H01L 23/00; H01L 25/065; H01L 25/18; H05K 1/09; H05K 1/11; H05K 1/18; H10B 80/00; H10D 80/30

(52) U.S. Cl. CPC H10W 70/65; H05K 1/09; H05K 1/112; H05K 1/181; H10W 70/685; H10W 70/69; H10W 90/00; H05K 2201/0191; H05K 2201/09036; H05K 2201/09227; H05K 2201/10159; H05K 2201/10212; H05K 2201/10234; H05K 2201/10522; H05K 2201/10734; H10B 80/00; H10D 80/30; H10W 70/05; H10W 70/095; H10W 74/15; H10W 90/724; H10W 90/734

(57) ABSTRACT

A semiconductor package includes a package substrate, a semiconductor chip on an upper surface of the package substrate, a mold layer covering the semiconductor chip, and external connection terminals on a lower surface of the package substrate, wherein the package substrate includes a core layer, lower wirings on a lower surface of the core layer, a solder resist layer covering the lower wirings, a trench exposing an inner surface of the solder resist layer and side surfaces of the lower wirings, and an insulating structure filling the trench, the solder resist layer includes openings exposing a portion of lower surfaces of the lower wirings, the external connection terminals are respectively disposed on the lower surfaces of the lower wirings exposed by the openings, and the insulating structure includes an insulating material different from that of the solder resist layer.

### CROSS-REFERENCE TO RELATED APPLICATIONS

This U.S. non-provisional patent application claims priority under 35 U.S.C. § 119 to Korean Patent Application No. 10-2024-0197661, filed on Dec. 26, 2024, in the Korean Intellectual Property Office, the entire contents of which are hereby incorporated by reference.

### BACKGROUND

The inventive concept relates to a semiconductor package.

A package technology is being researched to protect a semiconductor chip, transmit an electrical signal to an external circuit, and dissipate heat. In the package technology, performance may be maximized by combination of a semiconductor substrate. The package substrate may electrically connect a semiconductor chip and an external board, and mechanically support the semiconductor chip. Semiconductor chips are becoming highly integrated and miniaturized, and as a result, the package substrate is also required to have high-density wiring, high heat dissipation performance, and stable electrical characteristics.

### SUMMARY

An object of the inventive concept is to provide a semiconductor package having improved reliability including a package substrate having improved reliability.

The problem to be solved by the inventive concept is not limited to the problems mentioned above, and other problems not mentioned may be clearly understood by those skilled in the art from the description below.

A semiconductor package according to some embodiments of the inventive concept includes a package substrate, a semiconductor chip on an upper surface of the package substrate, a mold layer covering the semiconductor chip, and external connection terminals on a lower surface of the package substrate, wherein the package substrate includes a core layer, lower wirings on a lower surface of the core layer, a solder resist layer covering the lower wirings, a trench exposing an inner surface of the solder resist layer and side surfaces of the lower wirings, and an insulating structure filling the trench, the solder resist layer includes openings exposing a portion of lower surfaces of the lower wirings, the external connection terminals are respectively disposed on the lower surfaces of the lower wirings exposed by the openings, and the insulating structure includes an insulating material different from that of the solder resist layer.

A semiconductor package according to some embodiments of the inventive concept includes a package substrate, a semiconductor chip on an upper surface of the package substrate, a mold layer covering the semiconductor chip, and external connection terminals disposed on a lower surface of the package substrate, wherein the package substrate includes a core layer, lower wirings, and a dummy wiring on a lower surface of the core layer, a solder resist layer covering the lower wirings and the dummy wiring, an insulating structure penetrating the solder resist layer and covering side surfaces of the lower wirings and a side surface of the dummy wiring, and a first metal pattern on a lower surface of the dummy wiring, the solder resist layer includes first openings exposing a portion of lower surfaces of the lower wirings and a second opening exposing a portion of the lower surfaces of the dummy wiring, the external connection terminals are respectively disposed on the lower surfaces of the lower wirings exposed by the first openings, the first metal pattern is disposed in the second opening, the insulating structure includes an insulating material different from that of the solder resist layer, the lower wirings and the dummy wiring include a first metal, and the first metal pattern includes a second metal different from the first metal.

A semiconductor package according to some embodiments of the inventive concept includes a package substrate, a first semiconductor chip and a second semiconductor chip on an upper surface of the package substrate and horizontally spaced from each other, a mold layer covering the first semiconductor chip and the second semiconductor chip, and external connection terminals on a lower surface of the package substrate, wherein the package substrate includes a core layer, lower wirings on a lower surface of the core layer, a solder resist layer covering the lower wirings, and an insulating structure in direct contact with side surfaces of the lower wirings, the insulating structure includes at least one of an epoxy-based polymer, a polyimide-based polymer, a silicon-based polymer, and a polybenzoxazole (PBO)-based polymer, a horizontal width of the insulating structure decreases from a lower surface to an upper surface of the insulating structure, and a level of the lower surface of the insulating structure is equal to or higher than a level of the lower surface of the solder resist layer and equal to or lower than a level of a lower surface of each of the lower wirings.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view of a semiconductor package according to some example embodiments.

FIG. 2 is a plan view schematically illustrating a lower surface of the package substrate of FIG. 1.

FIG. 3 is an enlarged view of ‘EV1’ of FIG. 1.

FIG. 4 is an enlarged view of ‘EV2’ of FIG. 3.

FIG. 5 is an enlarged view corresponding to ‘EV2’ of FIG. 3.

FIG. 6 is an enlarged view corresponding to ‘EV2’ of FIG. 3.

FIGS. 7A, 8A, 9A, and 10A are plan views illustrating a manufacturing process of a semiconductor package according to some example embodiments.

FIGS. 7B, 8B, 9B, and 10B are enlarged views illustrating a manufacturing process of a semiconductor package according to some example embodiments.

FIG. 11 is a plan view schematically illustrating a lower surface of a package substrate according to some example embodiments.

FIG. 12 is an enlarged view of a package substrate according to some example embodiments.

FIGS. 13A and 14A are plan views illustrating a manufacturing process of a semiconductor package according to some example embodiments.

FIGS. 13B and 14B are enlarged views illustrating a manufacturing process of a semiconductor package according to some example embodiments.

### DETAILED DESCRIPTION

Hereinafter, a semiconductor package according to the inventive concept will be described with reference to the drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

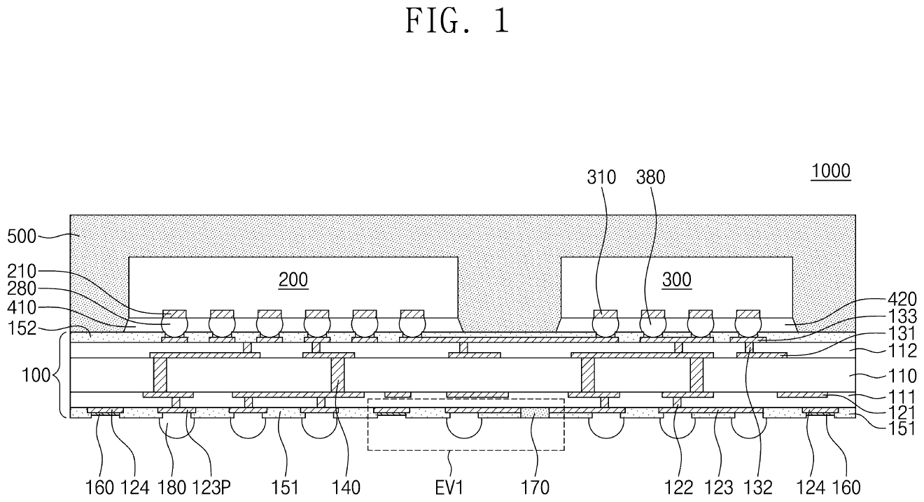

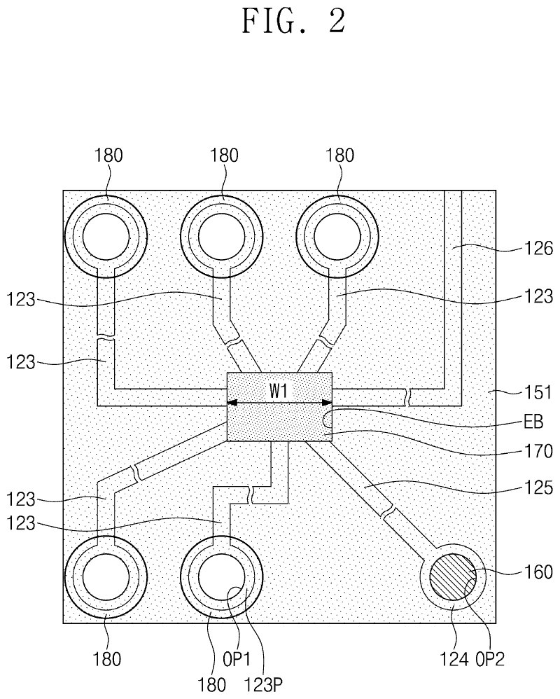

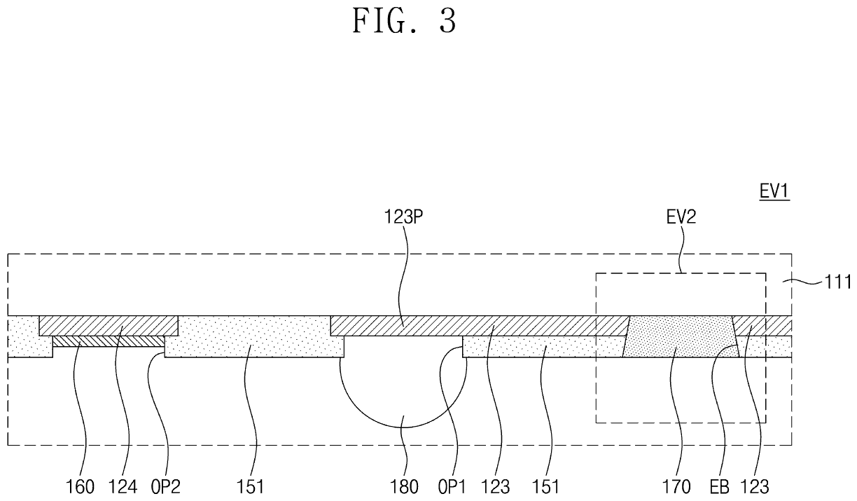

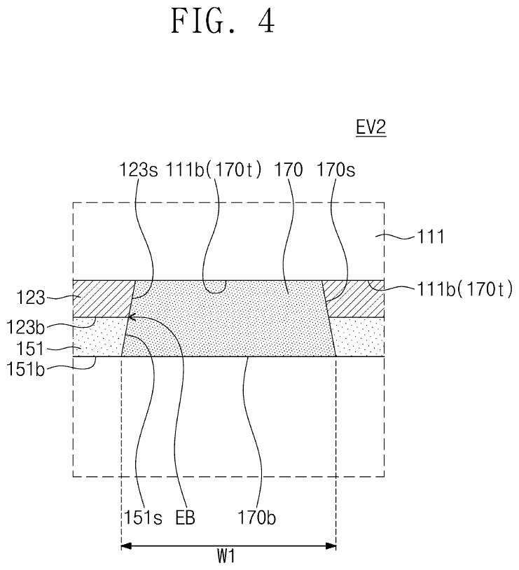

FIG. 1 is a cross-sectional view of a semiconductor package according to some example embodiments. FIG. 2 is a plan view schematically illustrating a lower surface of the package substrate of FIG. 1. FIG. 3 is an enlarged view of ‘EV1’ of FIG. 1. FIG. 4 is an enlarged view of ‘EV2’ of FIG. 3.

Referring to FIG. 1, a semiconductor package 1000 may be provided. The semiconductor package 1000 may include a package substrate 100, at least one semiconductor chip 200 and/or 300, external connection terminals 180, and a mold layer 500.

The package substrate 100 may be, for example, a printed circuit board (PCB).

The package substrate 100 may include a core layer 110, a core penetration via 140 first lower wirings 121, lower vias 122, second lower wirings 123, a lower insulating layer 111, a lower solder resist layer 151, first upper wirings 131, upper vias 132, second upper wirings 133, an upper insulating layer 112, an upper solder resist layer 152, a metal pattern 160, and an insulating structure 170.

The core layer 110 may have the largest thickness in the package substrate 100. For example, a thickness in a vertical direction of the core layer 110 may be greater than a thickness in the vertical direction of each of the lower insulating layer 111, the lower solder resist layer 151 the upper insulating layer 112, and the upper solder resist layer 152. The vertical direction may be a direction that is perpendicular to an upper surface of the package substrate 100. Forming the package substrate 100 may include preparing the core layer 110, forming the core penetration via 140 penetrating the core layer 110, the insulating layers 111 and 112, solder resist layer 151 and 152, the wirings 121, 123, 131, and 133, and the vias 122 and 132 on upper and lower surfaces of the core layer 110.

The core penetration via 140 may penetrate the core layer 110 and connect the first lower wirings 121 and the first upper wirings 131 to each other. In example embodiments, upper and lower surfaces of the core penetration via 140 may be coplanar with upper and lower surfaces, respectively, of the core layer 110. The first lower wirings 121 may be disposed on a lower surface of the core layer 110. The first lower wirings 121 may contact the lower surface of the core layer 110. The lower insulating layer 111 may be disposed on the lower surface of the core layer 110 to cover the first lower wirings 121. The lower insulating layer 111 may contact the lower surface of the core layer 110 and lower and side surfaces of the first lower wirings 121. The lower vias 122 may penetrate the lower insulating layer 111 to connect the first lower wirings 121 and the second lower wirings 123 to each other. The lower vias 122 may contact a lower surface of the first lower wirings 121 and an upper surface of the second lower wirings 123. The second lower wirings 123 and first dummy wirings 125 may be disposed on a lower surface of the lower insulating layer 111. The second lower wirings 123 and first dummy wirings 125 may contact the lower surface of the lower insulating layer 111. The lower solder resist layer 151 may be disposed on the lower surface of the lower insulating layer 111. The lower solder resist layer 151 may cover a portion of the second lower wirings 123 and a portion of the first dummy wirings 125. For example, the lower solder resist layer 151 may contact the lower surface of the lower insulating layer 111 and portions of the second lower wirings 123 and the first dummy wirings 125. The first upper wirings 131 may be disposed on the upper surface of the core layer 110. The first upper wirings 131 may contact the upper surface of the core layer 110. The upper insulating layer 112 may be disposed on the upper surface of the core layer 110 to cover the first upper wirings 131. The upper insulating layer 112 may contact the upper surface of the core layer 110 and contact upper and side surfaces of the first upper wirings 131. The upper vias 132 may penetrate the upper insulating layer 112 to connect the first upper wirings 131 and the second upper wirings 133 to each other. The upper vias 132 may contact upper surfaces of the first upper wirings 131 and lower surfaces of the second upper wirings 133. The second upper wirings 133 may be disposed on an upper surface of the upper insulating layer 112. The second upper wirings 133 may contact the upper surface of the upper insulating layer 112. The upper solder resist layer 152 may be disposed on the upper surface of the upper insulating layer 112. The upper solder resist layer 152 may cover a portion of the second upper wirings 133. The upper solder resist layer 152 may contact the upper surface of the upper insulating layer 112 and portions of the upper and side surfaces of the second upper wirings 133. The core layer 110, the lower insulating layer 111, and the upper insulating layer 112 may be formed of or include, for example, a composite material in which a glass fiber fabric is impregnated with an epoxy resin. The core penetration via 140, the first lower wirings 121, the lower vias 122, the second lower wirings 123, the first dummy wirings 125, the first upper wirings 131, the upper vias 132, and the second upper wirings 133 may be formed of or include a metal, for example, copper. Although each of the lower wirings 121 and 123 and the upper wirings 131 and 133 is illustrated as having two layers of wirings, the number of layers of wirings may be greater.

According to some embodiments, the first lower wirings 121, the lower vias 122, the lower solder resist layer 151, the first upper wirings 131, the upper vias 132, and the upper insulating layer 112 may be omitted. For example, the second lower wirings 123 may be disposed directly on the lower surface of the core layer 110, and the second upper wirings 133 may be disposed directly on the upper surface of the core layer 110. That is, in some embodiments, the package substrate 100 may include a single layer of wirings on each of the upper surface and the lower surface.

Details regarding an insulating structure 170 and a metal pattern 160 will be described later.

At least one semiconductor chip 200 and/or 300 may be disposed on an upper surface of the package substrate 100. A plurality of semiconductor chips 200 and 300 may be provided, for example, and may include a first semiconductor chip 200 and a second semiconductor chip 300. The first semiconductor chip 200 and the second semiconductor chip 300 may be spaced apart in a horizontal direction. The horizontal direction may be a direction that is parallel to an upper surface of the package substrate 100. The first semiconductor chip 200 and the second semiconductor chip 300 may be chips of the same type or chips of different types. For example, each of the first semiconductor chip 200 and the second semiconductor chip 300 may be one of a central processing unit (CPU), a graphics processing unit (GPU), an application processor (AP), a dynamic random-access memory (DRAM), a static random-access memory (SRAM), a flash memory, an application-specific integrated circuit (ASIC), and a system on chip (SoC).

The first semiconductor chip 200 may include first chip pads 210, and the second semiconductor chip 300 may include second chip pads 310. The first semiconductor chip 200 may be electrically connected to the package substrate 100 using first connection terminals 280 disposed between the first chip pads 210 and the package substrate 100. The second semiconductor chip 300 may be electrically connected to the package substrate 100 using second connection terminals 380 disposed between the second chip pad 310 and the package substrate 100. Specifically, the first connection terminals 280 and the second connection terminals 380 may be respectively disposed on the second upper wirings 133 exposed by the upper solder resist layer 152. For example, the first connection terminals 280 and the second connection terminals 380 may contact the second upper wirings 133 exposed by the upper solder resist layer 152. The first semiconductor chip 200 and the second semiconductor chip 300 may be electrically connected to each other through the package substrate 100. Each of the first connection terminals 280 and the second connection terminals 380 may be at least one of a bump and a pillar, and may include a conductive material such as solder. As another example, the first chip pads 210 and the second chip pads 310 may be disposed on an upper surface of the first semiconductor chip 200 and an upper surface of the second semiconductor chip 300, respectively, and the first connection terminals 280 and the second connection terminals 380 may be bonding wires.

A first underfill 410 may be interposed between the first semiconductor chip 200 and t he package substrate 100. The first underfill 410 may contact a lower surface of the first semiconductor chip 200, an upper surface of the upper solder resist layer 152, and side surfaces of the first connection terminals 280. A second underfill 420 may be interposed between the second semiconductor chip 300 and the package substrate 100. The second underfill 420 may contact a lower surface of the second semiconductor chip 300, the upper surface of the upper solder resist layer 152, and side surfaces of the second connection terminals 380. The first underfill 410 and the second underfill 420 may be formed from an epoxy resin-based composition.

The mold layer 500 may cover the upper surface and side surfaces of the first semiconductor chip 200, the upper surface and side surfaces of the second semiconductor chip 300, and the upper surface of the package substrate 100. The mold layer 500 may be formed of or include, for example, an epoxy molding compound. The mold layer 500 may cover side surfaces of the first underfill 410 and the second underfill 420. According to some embodiments, the first underfill 410 and the second underfill 420 may be omitted. In this case, the mold layer 500 may extend between the first semiconductor chip 200 and the package substrate 100 and between the second semiconductor chip 300 and the package substrate 100.

Referring to FIGS. 1, 2, and 3, the second lower wirings 123 may include substrate lower pads 123P. The substrate lower pads 123P may also be referred to as ball lands 123P. The substrate lower pad 123P may have a shape of a circle or a shape similar to a circle when viewed in a plan view. Each of the first dummy wirings 125 may include an alignment mark 124. The alignment mark 124 may have a shape of a circle or a shape similar to a circle, for example, when viewed in a plan view. The substrate lower pad 123P and the alignment mark 124 have been described as having a shape of a circle or a shape similar to a circle, but may have other shapes such as a square. For example, the alignment mark may be used as a reference point for aligning a drilling position in a laser drilling process described below, or as a reference point for component mounting alignment, etc.

A lower solder resist layer 151 may include a first opening OP1 and a second opening OP2. The first opening OP1 may expose a portion of a lower surface of the substrate lower pad 123P. The second opening OP2 may expose a portion of the lower surface of the alignment mark 124. That is, the lower solder resist layer 151 may cover the side surface and the edge portion of the lower surface of the lower pad 123P of the substrate and the side surface and the edge portion of the lower surface of the alignment mark 124. For example, the lower solder resist layer 151 may contact the side surface and the edge portion of the lower surface of the lower pad 123P of the substrate and the side surface and the edge portion of the lower surface of the alignment mark 124. Although not illustrated, according to some embodiments, the first opening OP1 may expose the entire lower surface of the lower pad 123P of the substrate, and the second opening OP2 may expose the entire lower surface of the alignment mark 124.

The external connection terminal 180 may be disposed on the lower surface of the substrate lower pad 123P exposed by the first opening OP1. The external connection terminal 180 may contact the lower surface of the substrate lower pad 123P exposed by the first opening OP1. The external connection terminal 180 may fill the first opening OP1. The metal pattern 160 may be disposed on the lower surface of the alignment mark 124 exposed by the second opening OP2. The metal pattern 160 may contact the lower surface of the alignment mark 124 exposed by the second opening OP2. The metal pattern 160 may include a different metal from those of the second lower wiring 123 and the first dummy wirings 125. For example, the metal pattern 160 may be a single metal layer or a plurality of metal layers, and may include a metal such as nickel and gold. For example, the metal pattern 160 may include a nickel layer of the alignment mark 124 and a gold layer on the nickel layer. A lower surface of the metal pattern 160 may be positioned at a higher level than a lower surface of the lower solder resist layer 151.

The package substrate 100 may further include a second dummy wiring 126 disposed on a lower surface of the lower insulating layer 111. The second dummy wiring 126 may be omitted according to some embodiments. The second dummy wiring 126 may be disposed at the same level as the first dummy wirings 125 and the second lower wirings 123. The second dummy wiring 126 may include the same metal as the first dummy wirings 125 and the second lower wirings 123. The second dummy wiring 126 may be formed of or include, for example, copper. The lower solder resist layer 151 may cover a lower surface and a side surface of the second dummy wiring 126. For example, the lower solder resist layer 151 may c ontact the lower and side surfaces of the second dummy wiring 126.

A trench EB exposing an inner surface 151s of the lower solder resist layer 151, side surfaces 123s of the second lower wirings 123, and a lower surface 111b of the lower insulating layer 111 may be provided. The trench EB may expose a side surface of the first dummy wiring 125 and a side surface of the second dummy wiring 126, as shown in FIG. 3.

The insulating structure 170 may be disposed in the trench EB. The insulating structure 170 may include an insulating material different from that of the lower solder resist layer 151. The insulating structure 170 may be formed of or include, for example, at least one of an epoxy-based polymer, a polyimide-based polymer, a silicon-based polymer, and a polybenzoxazole (PBO)-based polymer. For example, the insulating structure 170 may be formed of or include a low viscosity underfill material, and the insulating structure 170 may include a composition based on a lower viscosity epoxy resin than the first underfill 410 and the second underfill 420.

The insulating structure 170 may penetrate the lower solder resist layer 151 and cover the side surfaces 123s of the second lower wirings 123. The insulating structure 170 may include side surface 170s, and the side surface 170s of the insulating structure 170 may be in direct contact with the inner surface 151s of the lower solder resist layer 151, the side surface 123s of the second lower wirings 123, and the lower surface 111b of the lower insulating layer 111. The insulating structure 170 may not expose the side surface 123s of t he second lower wirings 123. The insulating structure 170 may have a width of an upper surface 170t less than a width of a lower surface 170b. For example, a horizontal width of the insulating structure 170 may become smaller from the bottom to the top. For example, a level of the lower surface 170b of the insulating structure 170 may be the same as a level of a lower surface 151b of the lower solder resist layer 151. For example, the upper surface 170t of the insulating structure 170 may be coplanar with an upper surface of second lower wirings 123, and the lower surface 170b of the insulating structure 170 may be coplanar with the lower surface 151b of the lower solder resist layer 151.

For example, a width W1 of the insulating structure 170 may be 50 μm to 300 μm or 50 μm to 150 μm. For example, the width W1 of a lower surface of the insulating structure 170 may be 150 μm. In example embodiments, the width W1 of the lower surface of the insulating structure 170 may be a maximum width.

As shown in FIG. 2, the second lower wirings 123 may extend toward the insulating structure 170. That is, the second lower wirings 123 may extend in different directions from the insulating structure 170. The first dummy wirings 125 and the second dummy wirings 126 may also extend toward the insulating structure 170. That is, the first dummy wirings 125 and the second dummy wirings 126 may extend in different directions from the insulating structure 170.

According to the inventive concept, the metal pattern 160 may prevent corrosion of the alignment mark 124. As described below, the metal pattern 160 may be formed by an electroplating method, and to facilitate the electroplating, the second lower wirings 123, the first dummy wirings 125, and the second dummy wirings 126 may be one united wiring that is integrally connected to each other. After the electroplating is completed, the trench EB may be formed to separate signal wirings or to separate different wirings (e.g., signal wirings, ground wirings, and power wirings). The trench EB is formed on the opposite surface of the package substrate 100 from the surface on which the semiconductor chips 200 and 300 are disposed, thereby increasing integration of the upper wirings 131 connecting the semiconductor chips 200 and 300. As a result, a size of the package substrate 100 may be reduced. The insulating structure 170 covers the side surfaces of the second lower wirings 123 exposed from the trench EB, thereby preventing corrosion of the second lower wirings 123 due to dust and solution ingress into the trench EB.

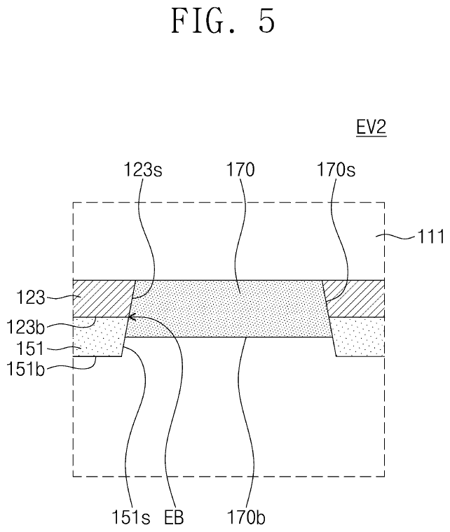

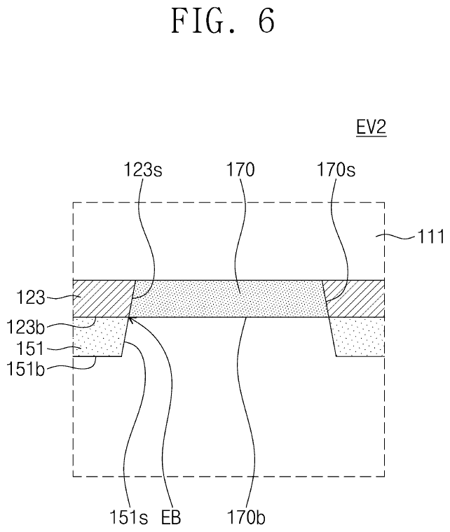

FIG. 5 is an enlarged view corresponding to ‘EV2’ of FIG. 3. FIG. 6 is an enlarged view corresponding to ‘EV2’ of FIG. 3. According to some embodiments, as shown in FIGS. 2 and 5, a level of the lower surface 170b of the insulating structure 170 may be disposed between a level of the lower surface 151b of the lower solder resist layer 151 and a level of a lower surface 123b of the second lower wiring 123. For example, the level of the lower surface 170b of the insulating structure 170 may be higher than the level of the lower surface 151b of the lower solder resist layer 151 and lower than the level of a lower surface 123b of the second lower wiring 123. According to some embodiments, as shown in FIGS. 2 and 6, a level of the lower surface 170b of the insulating structure 170 may be substantially the same as a level of the lower surface 123b of the second lower wiring 123. For example, the level of the lower surface 170b of the insulating structure 170 may be higher than the level of the lower surface 151b of the lower solder resist layer 151 and lower than a level of the lower surface 111b of the lower insulating layer 111.

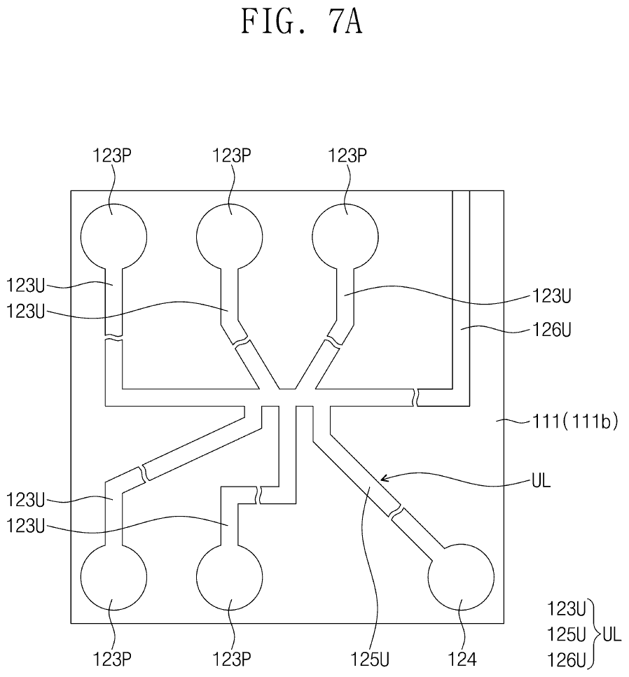

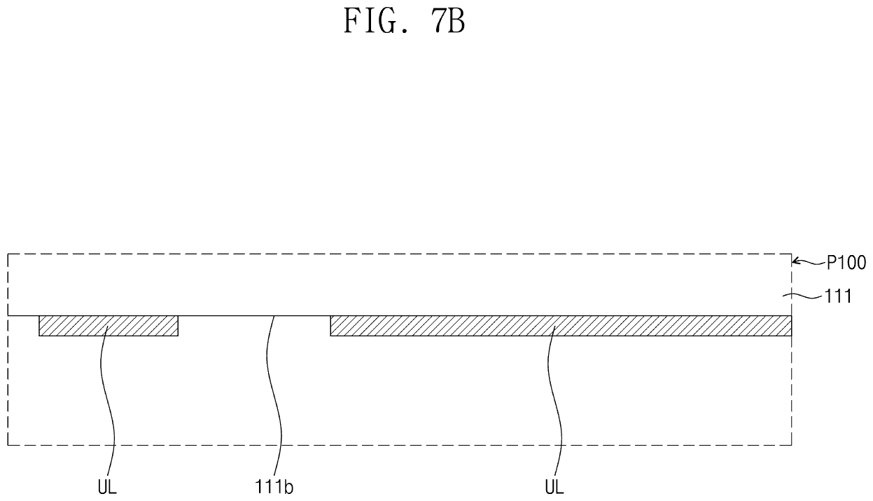

FIGS. 7A, 8A, 9A, and 10A are plan views illustrating a manufacturing process of a semiconductor package according to some example embodiments. FIGS. 7B, 8B, 9B, and 10B are enlarged views illustrating a manufacturing process of a semiconductor package according to some example embodiments. FIGS. 7B, 8B, 9B, and 10B correspond to FIGS. 7A, 8A, 9A, and 10A, respectively.

Referring to FIG. 7A and FIG. 7B, a preliminary package substrate P100 may be provided. The preliminary package substrate P100 may include, for example, the core layer 110, the core penetration via 140, the first lower wirings 121, the lower vias 122, the lower insulating layer 111, the first upper wirings 131, the upper vias 132, the second upper wirings 133, and the upper insulating layer 112 of FIG. 1.

A united metal line UL may be formed on a lower surface 111b of the lower insulating layer 111. The united metal line UL may be formed of or include, for example, copper. Forming the united metal line UL may include forming a metal layer on the lower surface 111b of the lower insulating layer 111 and patterning the metal layer. The united metal line UL may include a plating extension line 126U, a second preliminary lower wiring 123U, and a first preliminary dummy wiring 125U. The plating extension line 126U, the second preliminary lower wiring 123U, and the first preliminary dummy wiring 125U may be connected integrally without being separated from each other. The plating extension line 126U may be a portion that becomes the second dummy wiring 126 of FIGS. 2 and 3. The second preliminary lower wiring 123U may include a substrate lower pad 123P at one end, and the first preliminary dummy wiring 125U may include an alignment mark 124 at one end.

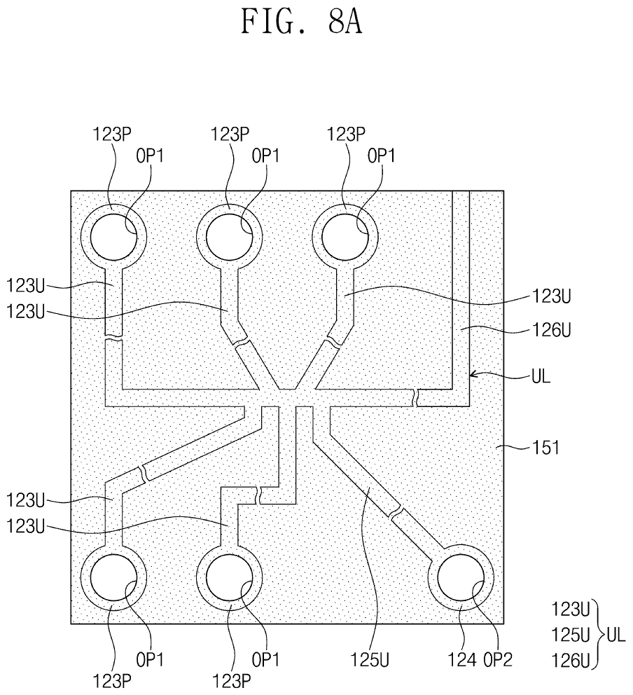

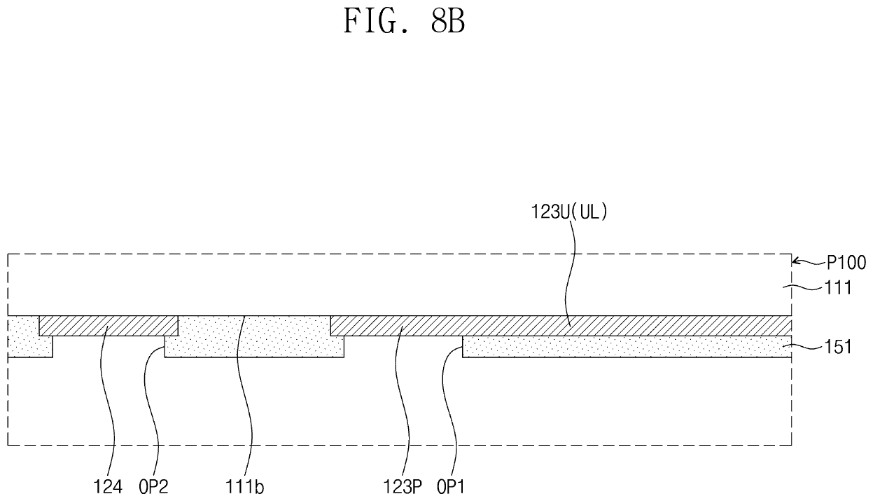

Referring to FIGS. 8A and 8B, a lower solder resist layer 151 including first openings OP1 and a second opening OP2 may be formed on the lower surface 111b of the lower insulating layer 111. Forming the lower solder resist layer 151 may include, for example, coating a solder resist material on the lower surface 111b of the lower insulating layer 111, and performing exposure, development, and curing processes on the solder resist material.

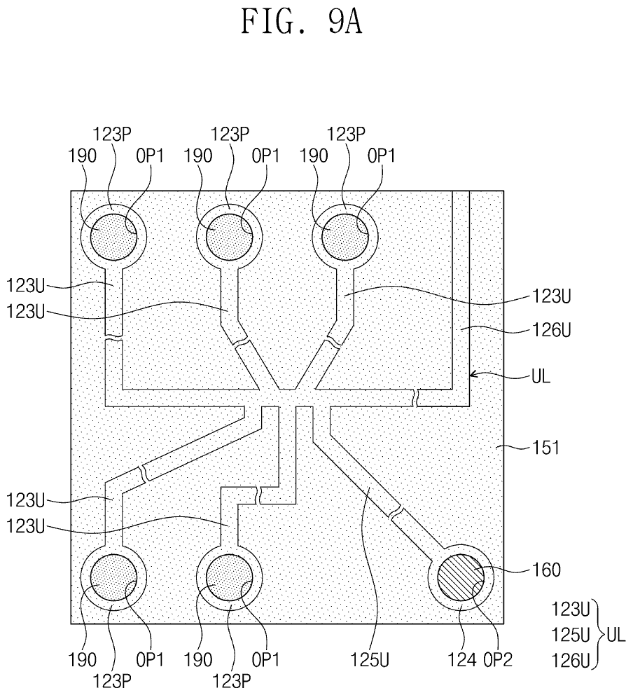

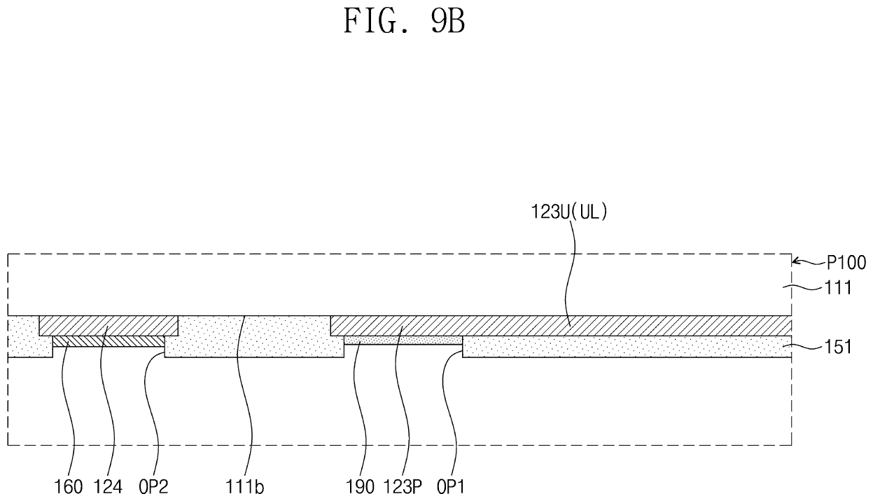

Referring to FIGS. 9A and 9B, an organic protective layer 190 (e.g., organic solderability preservative: OSP) may be selectively formed on the lower pads 123P of the substrate using a method such as dipping or spraying. A mask (e.g., polyimide tape) may be formed on an alignment mark 124, and the organic protective layer 190 may be not formed on the alignment mark 124. Afterwards, the mask may be removed after forming the organic protective layer 190 on the lower pad 123P of the substrate.

The plating extension line 126U may be connected to the plating lead line. The plating lead line may serve to supply current required for plating. The plating extension line 126U may be a metal line extending from the plating lead line to the plating region. Using an electroplating process, a metal pattern 160 may be formed on the alignment mark 124 exposed by the second opening OP2.

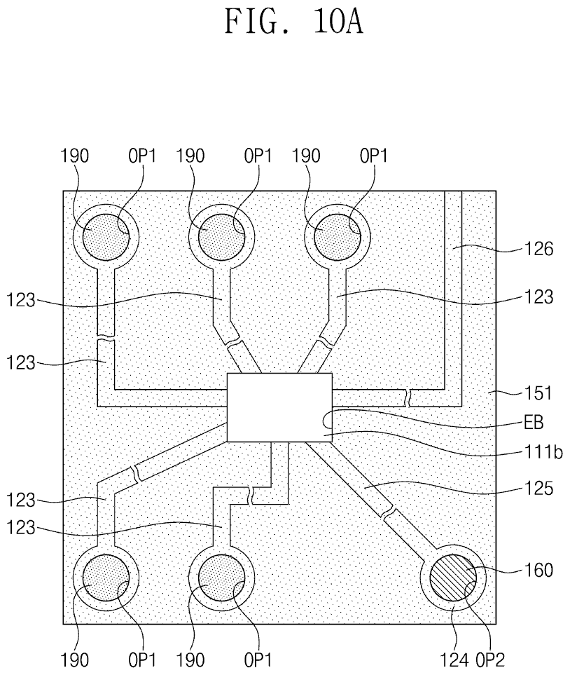

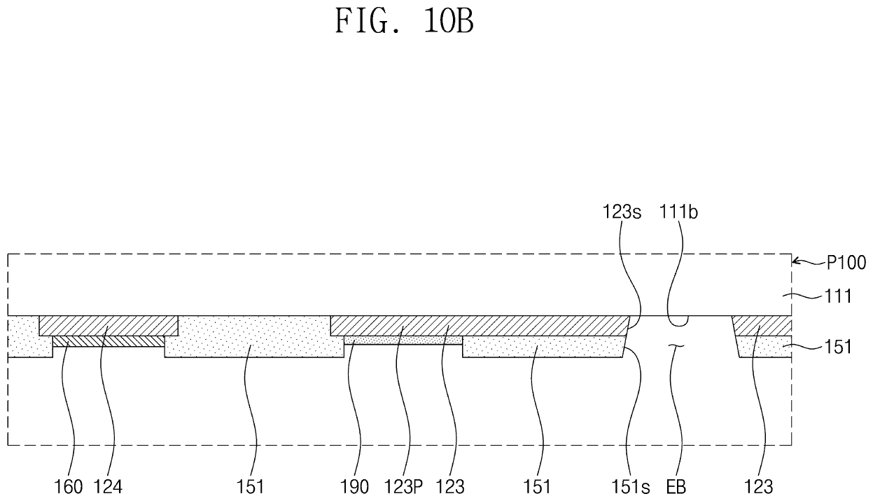

Referring to FIGS. 10A and 10B, a portion of the lower solder resist layer 151 and a portion of the united metal line UL may be removed to form a trench EB. The trench EB may be formed, for example, through a laser drilling process. By using the laser drilling process, the trench EB may have a shape having a wide lower width and a narrow upper width. For example, the trench EB may have a shape having a wider width at a level adjacent to the lower solder resist layer 151 and a narrower width at a level adjacent to the second lower wirings 123. By forming the trench EB, the united metal line UL may be separated into a plurality of wirings. Specifically, the united metal line UL may be separated to form a plurality of second lower wirings 123, a first dummy wiring 125, and a second dummy wiring 126. The second lower wirings 123, the first dummy wiring 125, and the second dummy wiring 126 may be formed from the second preliminary lower wirings 123U, the first preliminary dummy wiring 125U and the plating extension line 126U, respectively. The plurality of second lower wirings 123 may be separated from one integrated body, and thus an electrical short may not occur, and each of the plurality of second lower wirings 123 may transmit a different signal or perform a different role (e.g., voltage wiring, ground wiring). An inner surface 151s of the lower solder resist layer 151, a side surface 123s of the second lower wirings 123, a side surface of the first dummy wiring 125, and a side surface of the second dummy wiring 126 may be exposed by the trench EB.

Referring again to FIGS. 2 and 3, an insulating structure 170 may be formed in the trench EB. The insulating structure 170 may be formed by, for example, direct printing. The direct printing may be, for example, inkjet printing. The inkjet printing may be, for example, injecting an insulating ink into the trench EB using a nozzle. The insulating ink may include an insulating material other than the solder resist material. The insulating ink may include, for example, at least one of an epoxy-based polymer ink, a polyimide-based polymer ink, a silicon-based polymer ink, and a polybenzoxazole (PBO) ink.

According to the inventive concept, the inkjet printing process may accurately apply the insulating ink to the trench EB. The insulating ink may be formed of or include an insulating material having a low viscosity compared to the solder resist material. For example, the insulating ink may have a viscosity in the range of 5 to 25 mPa s. The solder resist material may not be suitable for filling the trench EB using inkjet printing due to a high viscosity thereof. A width of the trench EB may be, for example, 50 μm to 300 μm. When the width of the trench EB is small as described above, it may not be suitable to uniformly fill the trench EB using a high-viscosity insulating material such as a solder resist. The insulating ink has low viscosity, and thus the insulating ink may easily fill the width of the trench EB. In addition, the insulating ink may have sufficient adhesion to the lower solder resist layer 151 and the second lower wirings 123 when cured. As a result, the exposed side surface of the second lower wirings 123 may be protected by the insulating structure 170.

The upper solder resist layer 152 covering the second upper wirings 133 may be formed before or after the lower solder resist layer 151 is formed.

Thereafter, the external connection terminals 180 may then be attached to the substrate lower pads 123P, respectively. The organic protective layer 190 may be removed in a flux deposition before the external connection terminals 180 are attached, or in a reflow process after the external connection terminals 180 are attached. As a result, the external connection terminals 180 may be in direct contact with a lower surface of the substrate lower pads 123P. As a result, the package substrate 100 may be formed.

Additionally, the first semiconductor chip 200 and the second semiconductor chip 300 may be mounted on the package substrate 100 and the mold layer 500 is formed, thereby forming the semiconductor package 1000 of FIG. 1.

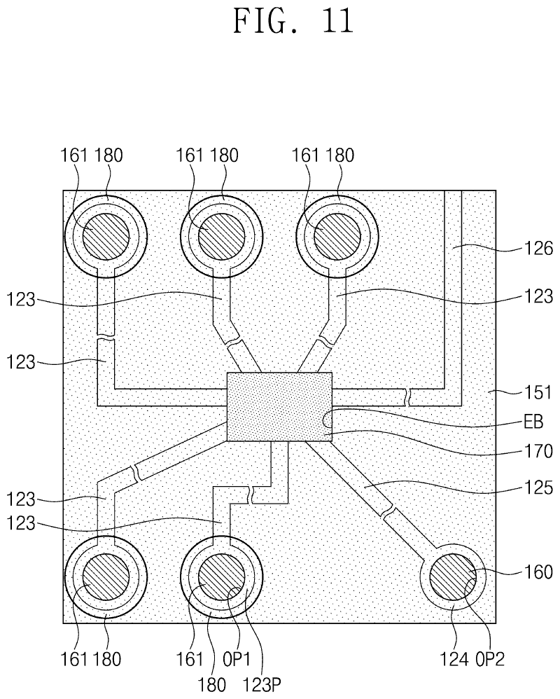

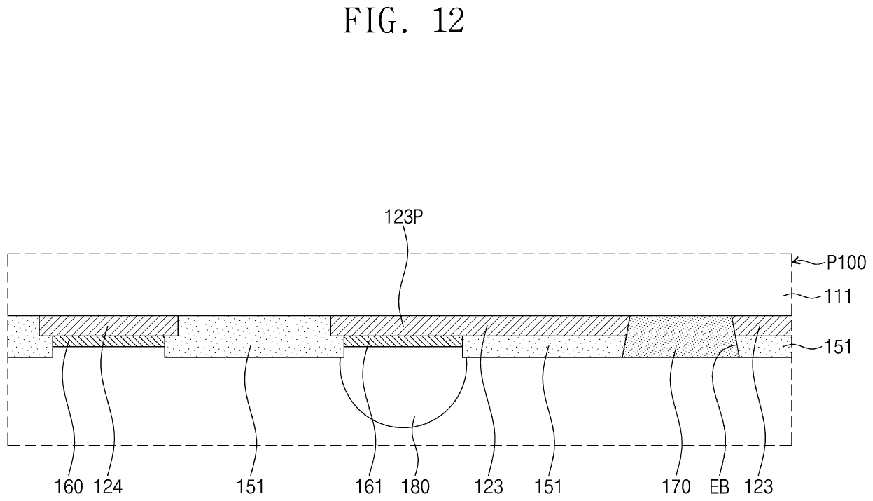

FIG. 11 is a plan view schematically illustrating a lower surface of a package substrate according to some example embodiments. FIG. 12 is an enlarged view of a package substrate according to some example embodiments. The description overlapping with that described in FIGS. 1 to 6 will not be repeated.

Referring to FIGS. 11 and 12, a second metal pattern 161 may be disposed on the lower surface of the substrate lower pad 123P. The metal pattern 160 may be referred to as a first metal pattern 160. The second metal pattern 161 may include the same metal material as the first metal pattern 160. For example, the second metal pattern 161 may include a nickel layer and a gold layer on the nickel layer. The second metal pattern 161 may fill a portion of the first opening OP1. The external connection terminal 180 may be spaced apart from the substrate lower pad 123P with the second metal pattern 161 interposed therebetween. That is, the external connection terminal 180 may be in direct contact with the lower surface of the second metal pattern 161.

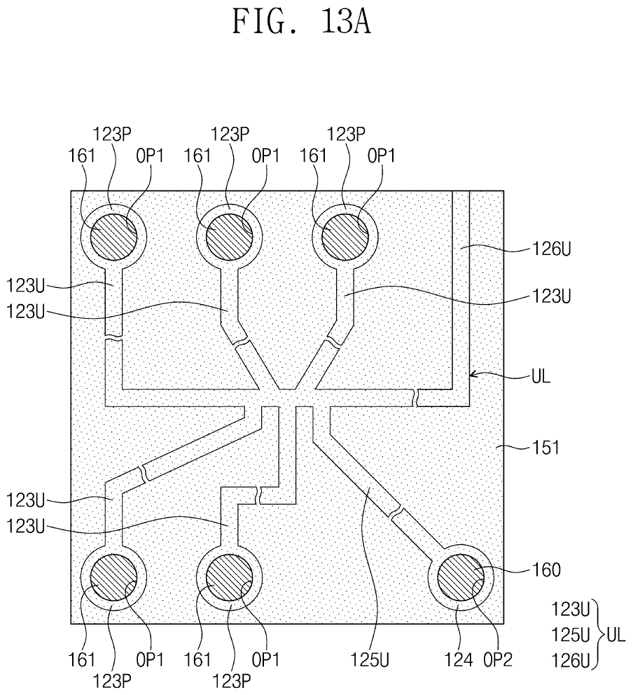

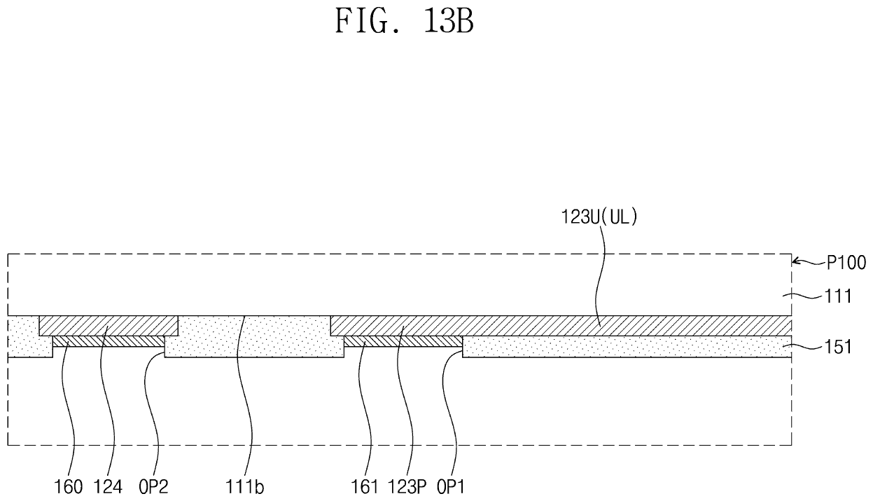

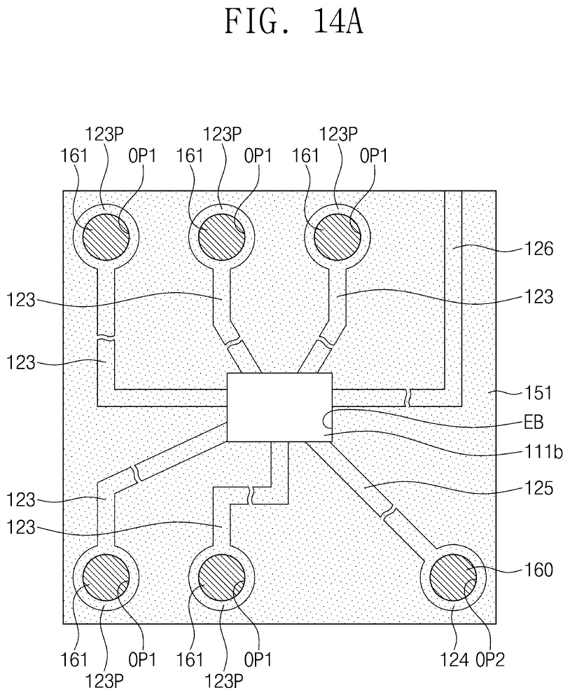

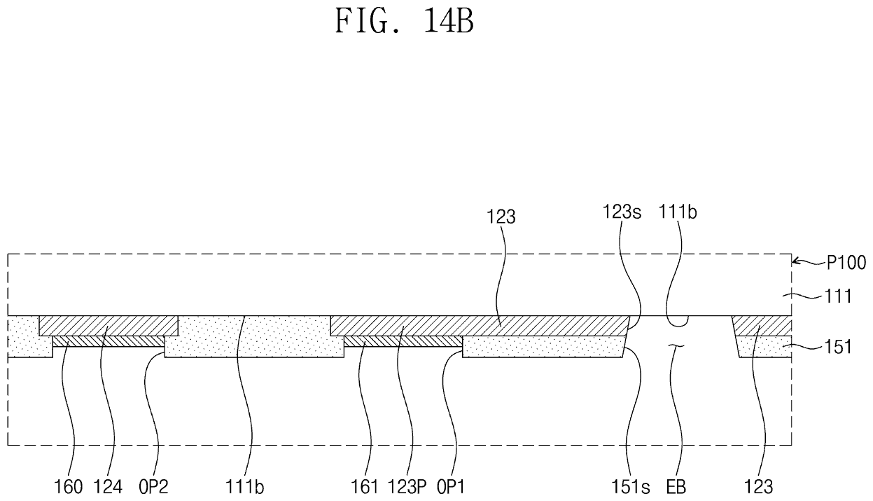

FIGS. 13A and 14A are plan views illustrating a manufacturing process of a semiconductor package according to some example embodiments.

FIGS. 13B and 14B are enlarged views illustrating a manufacturing process of a semiconductor package according to some example embodiments.

As described in FIGS. 8A, 8B, a lower solder resist layer 151 may be formed. Referring to FIGS. 13A and 13B, a second metal pattern 161 and a first metal pattern 160 may be formed on the substrate lower pad 123P exposed by the first opening OP1 and the alignment mark 124 exposed by the second opening OP2, respectively. The first metal pattern 160 and the second metal pattern 161 may be formed simultaneously, for example, by electroplating. The second metal pattern 161 may prevent corrosion of the substrate lower pad 123P and, when forming the external connection terminal 180, may have good wettability with the external connection terminal 180.

Referring to FIGS. 14A and 14B, a portion of the lower solder resist layer 151 and a portion of the united metal line UL may be removed to form a trench EB. The trench EB may be formed using substantially the same method as described above in FIGS. 10A and 10B. The upper solder resist layer 152 may be formed before or after the lower solder resist layer 151 is formed.

Referring again to FIGS. 11 and 12, external connection terminals 180 may be attached on the second metal pattern 161. The external connection terminals 180 may be in direct contact with a lower surface of the second metal pattern 161. As a result, the package substrate 100 may be formed.

According to the inventive concept, after plating, the wirings of the package substrate may be separated from each other through the trench, and the package substrate may include the insulating structure filling the trench. The insulating structure may be formed of a low-viscosity insulating material and may effectively fill the trench having the narrow width. The insulating structure may prevent the corrosion of the wiring due to the dust and solution in the trench. As a result, the reliability of the package substrate and the semiconductor package may be increased.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a package substrate;
a semiconductor chip on an upper surface of the package substrate;
a mold layer covering the semiconductor chip; and
external connection terminals on a lower surface of the package substrate,
wherein the package substrate includes:
a core layer;
lower wirings on a lower surface of the core layer;
a solder resist layer covering the lower wirings;
a trench exposing an inner surface of the solder resist layer and side surfaces of the lower wirings; and
an insulating structure filling the trench,
wherein the solder resist layer includes openings exposing a portion of lower surfaces of the lower wirings,
wherein the external connection terminals are respectively disposed on the lower surfaces of the lower wirings exposed by the openings, and
wherein the insulating structure includes an insulating material different from that of the solder resist layer.

2. The semiconductor package of claim 1, wherein the insulating structure includes at least one of an epoxy-based polymer, a polyimide-based polymer, a silicon-based polymer, and a polybenzoxazole (PBO)-based polymer.

3. The semiconductor package of claim 1, wherein the trench has a shape in which a width thereof decreases toward the core layer.

4. The semiconductor package of claim 1, wherein a level of a lower surface of the insulating structure is the same as a level of a lower surface of the solder resist layer.

5. The semiconductor package of claim 1, wherein a level of the lower surface of the insulating structure is between a level of a lower surface of the solder resist layer and a level of a lower surface of each of the lower wirings.

6. The semiconductor package of claim 1, wherein a level of a lower surface of the insulating structure is the same as a level of the lower surface of each of the lower wirings.

7. The semiconductor package of claim 1, wherein the insulating structure is in direct contact with the side surfaces of the lower wirings.

8. The semiconductor package of claim 1, wherein the lower wirings are spaced apart from each other with the insulating structure therebetween.

9. The semiconductor package of claim 1, wherein the lower wirings transmit different signals.

10. The semiconductor package of claim 1,
wherein the lower wirings include signal wiring, ground wiring, and power wiring, and
wherein each of the lower wirings is a different type of wiring.

11. The semiconductor package of claim 1, wherein the insulating structure has a horizontal width of 50 μm to 300 μm.

12. The semiconductor package of claim 1, wherein the insulating structure has a rectangular shape when viewed in a plan view.

13. A semiconductor package comprising:
a package substrate;
a semiconductor chip on an upper surface of the package substrate;
a mold layer covering the semiconductor chip; and
external connection terminals disposed on a lower surface of the package substrate,
wherein the package substrate includes:
a core layer;
lower wirings and a dummy wiring on a lower surface of the core layer;
a solder resist layer covering the lower wirings and the dummy wiring;
an insulating structure penetrating the solder resist layer and covering side surfaces of the lower wirings and a side surface of the dummy wiring; and
a first metal pattern on a lower surface of the dummy wiring,
wherein the solder resist layer includes first openings exposing a portion of lower surfaces of the lower wirings and a second opening exposing a portion of the lower surface of the dummy wiring,
wherein the external connection terminals are respectively disposed on the lower surfaces of the lower wirings exposed by the first openings,
wherein the first metal pattern is disposed in the second opening,
wherein the insulating structure includes an insulating material different from that of the solder resist layer,
wherein the lower wirings and the dummy wiring include a first metal, and
wherein the first metal pattern includes a second metal different from the first metal.

14. The semiconductor package of claim 13,
wherein the first metal is copper, and
wherein the second metal includes at least one of gold and nickel.

15. The semiconductor package of claim 13, wherein the external connection terminals are in direct contact with the exposed lower surfaces of the lower wirings.

16. The semiconductor package of claim 13, further including:
a second metal pattern interposed between the exposed lower surfaces of the lower wirings and the external connection terminals,
wherein the second metal pattern includes the second metal.

17. The semiconductor package of claim 13, wherein the insulating structure includes at least one of an epoxy-based polymer, a polyimide-based polymer, a silicon-based polymer, and polybenzoxazole (PBO).

18. The semiconductor package of claim 13, wherein the first metal pattern is horizontally spaced from the external connection terminals.

19. A semiconductor package comprising:
a package substrate;
a first semiconductor chip and a second semiconductor chip on an upper surface of the package substrate and horizontally spaced from each other;
a mold layer covering the first semiconductor chip and the second semiconductor chip; and
external connection terminals on a lower surface of the package substrate,
wherein the package substrate includes:
a core layer;
lower wirings on a lower surface of the core layer;
a solder resist layer covering the lower wirings; and
an insulating structure in direct contact with side surfaces of the lower wirings,
wherein the insulating structure includes at least one of an epoxy-based polymer, a polyimide-based polymer, a silicon-based polymer, and a polybenzoxazole (PBO)-based polymer,
wherein a horizontal width of the insulating structure decreases from a lower surface to an upper surface of the insulating structure, and
wherein a level of the lower surface of the insulating structure is equal to or higher than a level of the lower surface of the solder resist layer and equal to or lower than a level of a lower surface of each of the lower wirings.

20. The semiconductor package of claim 19, wherein the horizontal width of the insulating structure is 50 μm to 300 μm.
